(19) United States
(12) Patent Application Publication
(10) Pub. No.: US 2025/0215549 A1
(43) Pub. Date: Jul. 3, 2025

(54) MASK FRAME FOR EVAPORATION AND METHOD OF REPRODUCING THE SAME

(71) Applicant: LG Display Co., Ltd., Seoul (KR)

(72) Inventors: Jong-Hyun PARK, Paju-si (KR); Ho-Young LEE, Paju-si (KR); Jong-Hyun KIM, Paju-si (KR); Hyun-Su KWON, Paju-si (KR); Oh-Seob KWON, Paju-si (KR)

(21) Appl. No.: 18/966,588

(22) Filed: Dec. 3, 2024

(30) Foreign Application Priority Data
Dec. 27, 2023 (KR) 10-2023-0193350

(51) Int. Cl. C23C 14/04; C23C 14/24

(52) U.S. Cl. CPC C23C 14/042; C23C 14/24

(57) ABSTRACT

A mask frame for evaporation and a method of reproducing the same are provided. The mask frame for evaporation includes a first frame portion; a second frame portion on the first frame portion; a third frame portion on the second frame portion; a first hole provided in the first frame portion and the second frame portion; and a second hole provided in the third frame portion and connected to the first hole.

### CROSS-REFERENCE TO RELATED APPLICATION

The present application claims priority to Korean Patent Application No. 10-2023-0193350 filed in the Republic of Korea on Dec. 27, 2023, the entire contents of which are hereby expressly incorporated by reference into the present application.

### BACKGROUND

### Technical Field

The present disclosure relates to equipment for manufacturing organic light-emitting diode display devices, and more particularly, to a mask frame for evaporation and a method of reproducing the same.

### Description of the Related Art

As one of the flat panel display devices, an organic light-emitting diode display device has wide viewing angles, as compared with a liquid crystal display device, because it is self-luminous. The organic light-emitting diode display device also has advantages of a thin thickness, light weight and low power consumption because a backlight unit is not necessary.

In addition, the organic light-emitting diode display device is driven by low voltages of direct current (DC) and has a fast response time. Further, the organic light-emitting diode display device is strong against the external impacts and is used in a wide range of temperatures because its components are solids. Also, the organic light-emitting diode display device can be manufactured at low costs.

The organic light-emitting diode display device can include a plurality of pixels, each of which has red, green, and blue sub-pixels, and can display various color images by allowing the red, green, and blue sub-pixels to selectively emit light.

The red, green and blue sub-pixels can have red, green and blue light-emitting layers, respectively, and each light-emitting layer can be formed through a vacuum thermal evaporation process in which a luminous material is selectively deposited using a fine metal mask (FMM) or an open metal mask (OMM).

The fine metal mask or open metal mask can be used after being welded and fixed on a mask frame. At this time, various sizes and/or shapes of fine metal masks or open metal masks can be used depending on changes in the size of the display panel and/or the pixel size, and in response to this, repetitive polishing and welding works of the mask frame can be performed. In this process, the height and thickness of the mask frame can be reduced.

However, if the height of the mask frame is smaller than a predetermined value, it is impossible to align components in the evaporation equipment. As a result, the mask frame with the reduced height may be discarded and a new mask frame may be required, which increases the manufacturing costs.

### BRIEF SUMMARY

Accordingly, the present disclosure is to provide a mask frame for evaporation and a method of reproducing the same that substantially obviate one or more of the limitations and disadvantages described above and associated with the background art.

More specifically, an object of the present disclosure is to provide a reusable mask frame for evaporation and method of reproducing the same.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, as well as the appended drawings.

To achieve these and other aspects of the present disclosure, as embodied and broadly described herein, a mask frame for evaporation includes a first frame portion; a second frame portion on the first frame portion; a third frame portion on the second frame portion; a first hole provided in the first frame portion and the second frame portion; and a second hole provided in the third frame portion and connected to the first hole.

In another aspect, a method of reproducing a mask frame for evaporation includes preparing the mask frame including a first frame portion, a second frame portion on the first frame portion, and a first hole provided in the first frame portion and the second frame portion; flattening a top surface of the second frame portion by preprocessing the second frame portion; forming a third frame portion on the second frame portion; and forming a second hole in the third frame portion, the second hole connected to the first hole.

It is to be understood that both the foregoing general description and the following detailed description are examples and are intended to provide further explanation of the inventive concepts as claimed.

### BRIEF DESCRIPTION OF THE SEVERAL VIEWS OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic cross-sectional of the organic light-emitting diode display device according to an embodiment of the present disclosure;

FIG. 2 is a schematic perspective view of a mask assembly according to the embodiment of the present disclosure;

FIG. 3 is a schematic plan view of a mask frame according to the embodiment of the present disclosure;

FIG. 4 is a cross-sectional view corresponding to line I-I′ of FIG. 3;

FIG. 5 is a schematic cross-sectional view of a part of the mask frame according to the embodiment of the present disclosure;

FIG. 6 is a schematic cross-sectional view of another part of the mask frame according to the embodiment of the present disclosure;

FIG. 7 is a schematic cross-sectional view of a part of a reproduced mask frame according to the embodiment of the present disclosure;

FIG. 8 is a schematic cross-sectional view of another part of the reproduced mask frame according to the embodiment of the present disclosure;

FIGS. 9A to 9D are schematic cross-sectional views of a part of a mask frame in steps of reproducing the same according to the embodiment of the present disclosure;

FIGS. 10A to 10D are schematic cross-sectional views of another part of a mask frame in steps of reproducing the same according to the embodiment of the present disclosure;

FIGS. 11A and 11B are schematic cross-sectional views of a mask frame in steps of reproducing the same using an instrument according to the embodiment of the present disclosure; and

FIGS. 12A and 12B are schematic cross-sectional views of a mask frame in steps of reproducing the same using another instrument according to the embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure.

Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Hereinafter, exemplary embodiments of the present disclosure will be described in detail with reference to accompanying drawings.

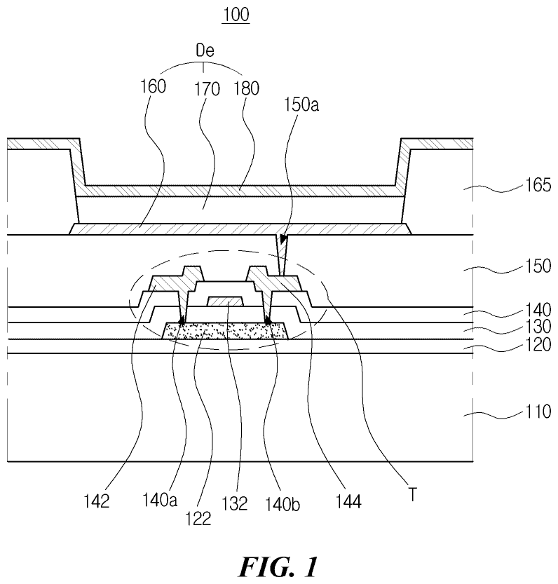

FIG. 1 is a schematic cross-sectional of the organic light-emitting diode display device according to an embodiment of the present disclosure and shows one sub-pixel.

As shown in FIG. 1 in the organic light-emitting diode display device 100 according to the embodiment of the present disclosure, a buffer layer 120 can be formed on a substrate 110. The buffer layer 120 can be disposed substantially on an entire surface of the substrate 110. The substrate 110 can be a glass substrate or a plastic substrate. For example, polyimide can be used as the plastic substrate, but embodiments of the present disclosure are not limited thereto. The buffer layer 120 can be formed of an inorganic material, such as silicon oxide (SiO₂) or silicon nitride (SiNx), and can be a single layer or multiple layers.

A patterned semiconductor layer 122 can be formed on the buffer layer 120. The semiconductor layer 122 can be formed of an oxide semiconductor material, and in this case, a light-shielding pattern can be further formed under the semiconductor layer 122. The light-shielding pattern can block light incident on the semiconductor layer 122 and can prevent the semiconductor layer 122 from deteriorating due to the light. Alternatively, the semiconductor layer 122 can be formed of polycrystalline silicon, and both ends of the semiconductor layer 122 can be doped with impurities.

A gate insulation layer 130 of an insulating material can be formed on the semiconductor layer 122 substantially over the entire surface of the substrate 110. The gate insulation layer 130 can be formed of an inorganic insulating material such as silicon oxide (SiO₂) or silicon nitride (SiNx). When the semiconductor layer 122 is made of an oxide semiconductor material, the gate insulation layer 130 can be formed of silicon oxide (SiO₂). Alternatively, when the semiconductor layer 122 is made of polycrystalline silicon, the gate insulation layer 130 can be formed of silicon oxide (SiO₂) or silicon nitride (SiNx).

A gate electrode 132 of a conductive material such as metal can be formed on the gate insulation layer 130 corresponding to the center of the semiconductor layer 122. In addition, a gate line and a first capacitor electrode can be formed on the gate insulation layer 130. The gate line can extend in a first direction, and the first capacitor electrode can be connected to the gate electrode 132.

In the embodiment of the present disclosure, the gate insulation layer 130 can be formed substantially over the entire surface of the substrate 110. However, the gate insulation layer 130 can be patterned to have the same shape as the gate electrode 132.

An interlayer insulation layer 140 made of an insulating material can be formed on the gate electrode 132 substantially over the entire surface of the substrate 110. The interlayer insulation layer 140 can be formed of an inorganic insulating material such as silicon oxide (SiO₂) or silicon nitride (SiNx). Alternatively, the interlayer insulation layer 140 can be formed of an organic insulating material such as photo acryl or benzocyclobutene.

The interlayer insulation layer 140 can have first and second contact holes 140a and 140b exposing top surfaces of both ends of the semiconductor layer 122. The first and second contact holes 140a and 140b can be disposed at both sides of the gate electrode 132 and spaced apart from the gate electrode 132. The first and second contact holes 140a and 140b can also be formed in the gate insulation layer 130. Alternatively, when the gate insulation layer 130 is patterned to have the same shape as the gate electrode 132, the first and second contact holes 140a and 140b can be formed only in the interlayer insulation layer 140.

Source and drain electrodes 142 and 144 of a conductive material such as metal can be formed on the interlayer insulation layer 140. In addition, a data line, a power supply line and a second capacitor electrode can be further formed on the interlayer insulation layer 140.

The source and drain electrodes 142 and 144 can be spaced apart from each other with the gate electrode 132 positioned therebetween and can be in contact with both ends of the semiconductor layer 122 through the first and second contact holes 140a and 140b, respectively. The data line can extend in a second direction and crosses the gate line to thereby define a pixel region corresponding to each sub-pixel. The power supply line for supplying a high potential voltage can be spaced apart from the data line. The second capacitor electrode can be connected to the drain electrode 144. The second capacitor electrode can overlap the first capacitor electrode to thereby constitute a storage capacitor with the interlayer insulation layer 140 therebetween as a dielectric. Alternatively, the first capacitor electrode can be connected to the drain electrode 144, and the second capacitor electrode can be connected to the gate electrode 132.

The semiconductor layer 122, the gate electrode 132, and the source and drain electrodes 142 and 144 can form a thin film transistor T. The thin film transistor T can have a coplanar structure in which the gate electrode 132 and the source and drain electrodes 142 and 144 are located at the same side with respect to the semiconductor layer 122.

Alternatively, the thin film transistor T can have an inverted staggered structure in which the gate electrode and the source and drain electrodes are located at different sides with respect to the semiconductor layer. That is, the gate electrode can be disposed under the semiconductor layer, and the source and drain electrodes can be disposed over the semiconductor layer. In this case, the semiconductor layer can be formed of oxide semiconductor or amorphous silicon.

An overcoat layer 150 of an insulating material can be formed on the source and drain electrodes 142 and 144 substantially over the entire surface of the substrate 110. The overcoat layer 150 can be formed of an organic insulating material such as photosensitive acrylic polymer (photo acryl) or benzocyclobutene. The overcoat layer 150 can have a flat top surface.

Meanwhile, an insulation layer of an inorganic insulating material such as silicon oxide (SiO₂) or silicon nitride (SiNx) can be further formed under the overcoat layer 150, that is, between the thin film transistor T and the overcoat layer 150.

The overcoat layer 150 can have a drain contact hole 150a exposing the drain electrode 144. The drain contact hole 150a can be spaced apart from the second contact hole 140b. Alternatively, the drain contact hole 150a can be disposed right over the second contact hole 140b.

A first electrode 160 can be formed on the overcoat layer 150 and formed of a conductive material having a relatively high work function. The first electrode 160 can be disposed in each sub-pixel and is in contact with the drain electrode 144 through the drain contact hole 150a. For example, the first electrode 160 can be formed of a transparent conductive material such as indium tin oxide (ITO) or indium zinc oxide (IZO), but embodiments of the present disclosure are not limited thereto.

The organic light-emitting diode display device according to the embodiment of the present disclosure can be a top emission type in which light of a light-emitting diode De is output toward a direction opposite the substrate 110. Accordingly, the first electrode 160 can further include a reflective electrode or a reflective layer formed of a metal material having a relatively high reflectance below the transparent conductive material. For example, the reflective electrode or reflective layer can be formed of an aluminum-palladium-copper (APC) alloy, silver (Ag) or aluminum (Al). The first electrode 160 can have a triple-layer structure of ITO/APC/ITO, ITO/Ag/ITO or ITO/Al/ITO, but embodiments of the present disclosure are not limited thereto.

A bank layer 165 of an insulating material can be formed on the first electrode 160. The bank layer 165 can overlap and cover edges of the first electrode 160 and expose a central portion of the first electrode 160.

The bank layer 165 can be formed as a single layer or multiple layers of an organic insulating material. For example, the bank layer 165 can be formed of polyimide, photosensitive acrylic polymer (photo acryl), or benzocyclobutene.

Next, a light-emitting layer 170 can be formed on the first electrode 160 exposed by the bank layer 165.

Although not shown in the figure, the light-emitting layer 170 can include a first charge auxiliary layer, a light-emitting material layer, and a second charge auxiliary layer sequentially disposed over the first electrode 160. The light-emitting material layer can be formed of any one of red, green and blue luminescent materials, but embodiments of the present disclosure are not limited thereto.

The first charge auxiliary layer can be a hole auxiliary layer, and the hole auxiliary layer can include at least one of a hole injecting layer (HIL) and a hole transporting layer (HTL). In addition, the second charge auxiliary layer can be an electron auxiliary layer, and the electron auxiliary layer can include at least one of an electron injecting layer (EIL) and an electron transporting layer (ETL). However, embodiments of the present disclosure are not limited thereto.

The light-emitting layer 170 can be formed through a thermal evaporation process. In this case, the light-emitting layer 170 can be formed only on the first electrode 160 exposed by the bank layer 165 using a fine metal mask.

Alternatively, in other embodiments, the light-emitting layer 170 can also be provided on the bank layer 165 using an open metal mask and formed substantially over an entire surface of the substrate 110.

A second electrode 180 of a conductive material having a relatively low work function is formed on the light-emitting layer 170 substantially over the entire surface of the substrate 110. The second electrode 180 can be formed of aluminum (Al), magnesium (Mg), silver (Ag), or an alloy thereof. The second electrode 180 has a relatively thin thickness such that light from the light-emitting layer 170 can be transmitted therethrough. Alternatively, the second electrode 180 can be formed of a transparent conductive material such as indium-gallium-oxide (IGO), but embodiments of the present disclosure are not limited thereto.

The first electrode 160, the light-emitting layer 170, and the second electrode 180 constitute a light-emitting diode De. The first electrode 160 can serve as an anode, and the second electrode 180 can serve as a cathode, but is not limited thereto.

As described above, the organic light-emitting diode display device according to the embodiment of the present disclosure can be a top emission type display device in which light from the light-emitting layer 170 of the light-emitting diode De is output toward a direction opposite the substrate 110, that is, output to the outside through the second electrode 180. The top emission type display device can have a wider emission area than a bottom emission type display device of the same size, to thereby improve luminance and reduce power consumption.

In this case, a capping layer can be formed on the second electrode 180 substantially over the entire surface of the substrate 110. The capping layer can be formed of an insulating material having a relatively high refractive index. The wavelength of light traveling along the capping layer can be amplified by surface plasma resonance, and thus the intensity of the peak can be increased, thereby improving the light efficiency in the top emission type organic light-emitting diode display device. For example, the capping layer can be formed as a single layer of an organic layer or an inorganic layer or formed as organic/inorganic stacked layers.

In addition, a protective layer and/or an encapsulation layer can be formed on the capping layer substantially over the entire surface of the substrate 110 to block moisture or oxygen introduced from the outside, thereby protecting the light-emitting diode De.

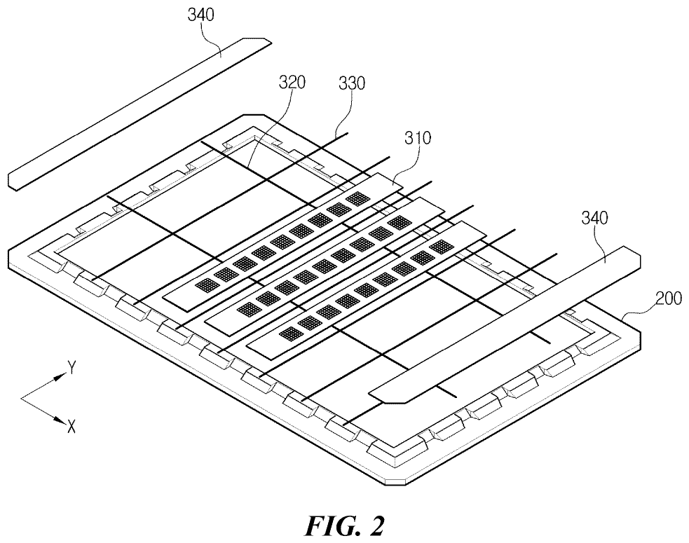

As described above, the light-emitting layer 170 according to the embodiment of the present disclosure can be formed using the fine metal mask or the open metal mask, and a mask assembly including the fine metal mask or the open metal mask will be described with reference to FIG. 2.

FIG. 2 is a schematic perspective view of a mask assembly according to the embodiment of the present disclosure.

In FIG. 2, the mask assembly according to the embodiment of the present disclosure can include a mask frame 200 and at least one metal mask 310.

The mask frame 200 can have a substantially rectangular shape and can include at least one opening therein. For example, the mask frame 200 can have a rectangular shape having long sides parallel to a first direction X and short sides parallel to a second direction Y. The mask frame 200 can be formed of a member having rigidity capable of supporting the metal mask 310.

The metal mask 310 can be provided on the mask frame 200. The metal mask 310 can have a stick shape extending in the second direction Y, and can be provided in plural. The metal mask 310 can be a fine metal mask having a hole corresponding to each sub-pixel.

However, embodiments of the present disclosure are not limited thereto. In other embodiments, the metal mask 310 can be an open metal mask having a hole corresponding to a display panel. In addition, the metal mask 310 may be provided in a plate shape substantially corresponding to a size of the mask frame 200.

The mask assembly according to the embodiment of the present disclosure can further include at least one first support 320 and/or at least one second support 330.

The first support 320 can be a long side support or a long side stick and can extend in the first direction X. The first support 320 can be disposed in plural across the opening of the mask frame 200 in the first direction X to thereby support the metal mask 310.

The second support 330 can be a short side support or a shield stick and can extend in the second direction Y. The second support 330 can be disposed in plural across the opening of the mask frame 200 in the second direction Y.

In addition, the mask assembly according to the embodiment of the present disclosure can further include a pair of align sticks 340. The pair of align sticks 340 can extend in the second direction Y and can be provided at both sides of the plurality of metal masks 310 arranged along the first direction X. That is, the plurality of metal masks 310 can be interposed between the pair of align sticks 340.

Meanwhile, the mask assembly according to the embodiment of the present disclosure can further include other supports or sticks.

Various components such as the metal masks 310, the first and second supports 320 and 330, and the align sticks 340 can be welded and fixed on the mask frame 200 to thereby be used for forming the light-emitting layer 170 of FIG. 1.

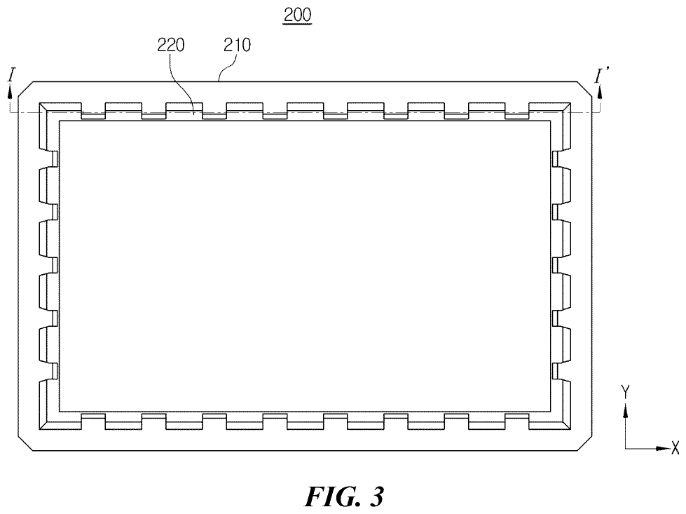

The mask frame 200 according to the embodiment of the present disclosure will be described in detail with reference to FIGS. 3 to 6.

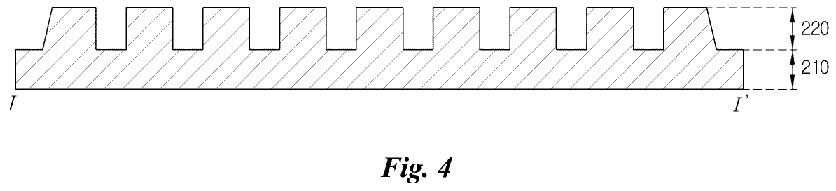

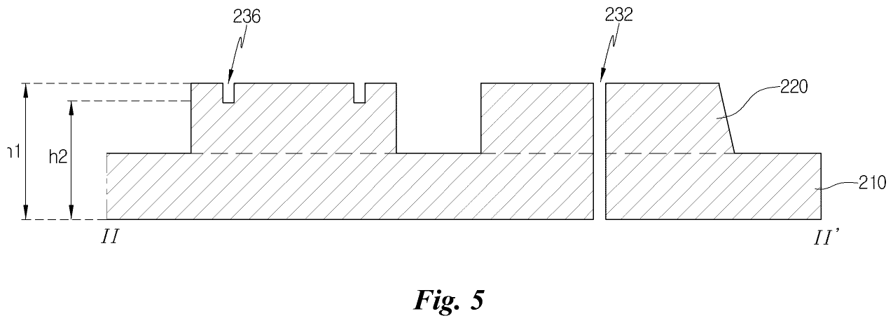

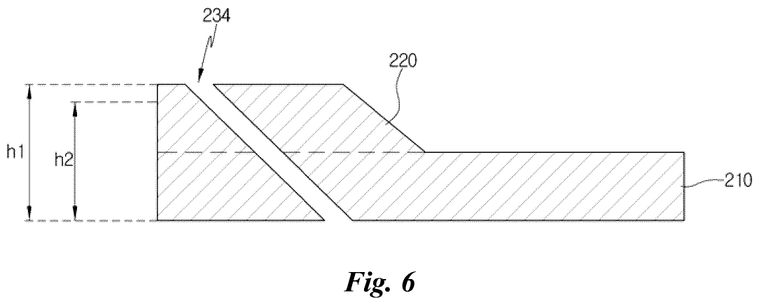

FIG. 3 is a schematic plan view of a mask frame according to the embodiment of the present disclosure, FIG. 4 is a cross-sectional view corresponding to line I-I′ of FIG. 3, FIG. 5 is a schematic cross-sectional view of a part of the mask frame according to the embodiment of the present disclosure, and FIG. 6 is a schematic cross-sectional view of another part of the mask frame according to the embodiment of the present disclosure. FIGS. 3 to 6 will be described with reference to FIG. 2 together.

In FIGS. 3 to 6, the mask frame 200 according to the embodiment of the present disclosure can include a first frame portion 210 and a plurality of second frame portions 220.

The first frame portion 210 can have a rectangular frame shape including an opening of a substantially rectangular shape. The plurality of second frame portions 220 can be provided on the first frame portion 210 to be adjacent to the opening and be spaced apart from each other. At least one of the plurality of second frame portions 220 can be provided with one of at least one hole 232, at least one oblique hole 234, and at least one groove 236. Each of the hole 232 and the oblique hole 234 can be provided in the first frame portion 210 and the second frame portion 220 and can be used to align the components of the mask assembly.

The at least one groove 236 can be provided at a top surface of the second frame portion 220 and may not be provided in the first frame portion 210. The at least one groove 236 can be used to weld the components of FIG. 2 on the mask frame 200. A depth of the at least one groove 236 can vary depending on the metal mask 310, the first and second supports 320 and 330, or the align stick 340 corresponding thereto, and can be several tens of μm or more, for example.

In addition, a trimming line or a cutting line can be provided to correspond to the second frame portion 220 of the mask frame 200 along the first direction X.

By the way, depending on the size of the display panel and/or the size of the pixel, the sizes and/or the fixed locations of the components of FIG. 2, that is, the metal mask 310, the first and second supports 320 and 330, and the align stick 340 are different. Accordingly, the mask frame 200 can be repeatedly polished and welded, and in this process, the height and thickness of the mask frame 200 can be reduced.

Namely, the mask frame 200 can initially have a first height h1, and through repeated polishing and welding works, the mask frame 200 can have a second height h2 lower than the first height h1.

In this case, when the second height h2 of the mask frame 200 is smaller than a predetermined value, it is impossible to align the components in the evaporation equipment. Accordingly, in the embodiment of the present disclosure, by reproducing the mask frame 200 with the reduced height, the mask frame 200 can have a height corresponding to the initial first height h1.

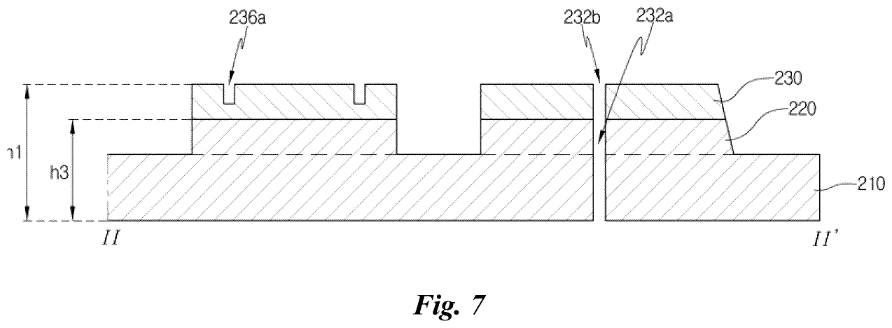

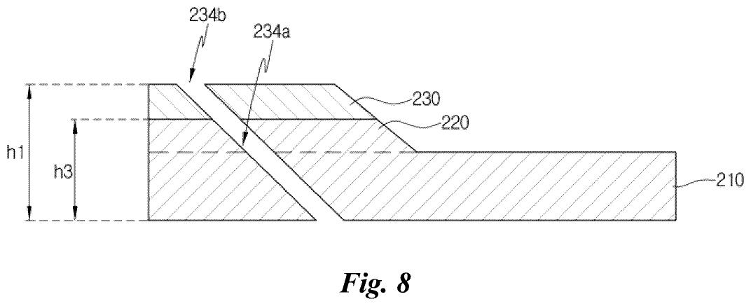

The configuration of the reproduced mask frame 200 according to the embodiment of the present disclosure will be described in detail with reference to FIG. 7 and FIG. 8.

FIG. 7 is a schematic cross-sectional view of a part of a reproduced mask frame according to the embodiment of the present disclosure, and FIG. 8 is a schematic cross-sectional view of another part of the reproduced mask frame according to the embodiment of the present disclosure. FIG. 7 and FIG. 8 will be described with reference to FIGS. 3 to 6 together.

In FIG. 7 and FIG. 8, the reproduced mask frame according to the embodiment of the present disclosure can include a first frame portion 210, a plurality of second frame portions 220, and a plurality of third frame portions 230.

The plurality of second frame portions 220 can be provided on the first frame portion 210 and be spaced apart from each other. The plurality of second frame portions 220 can be connected to the first frame portion 210 to form one body.

At least one first hole 232a and at least one first oblique hole 234a can be provided in the second frame portions 220. The first hole 232a and the first oblique hole 234a can be provided in the same second frame portion 220. Alternatively, the first hole 232a and the first oblique hole 234a can be provided in different second frame portions 220, respectively.

The first hole 232a and the first oblique hole 234a can extend and also be provided in the first frame portion 210.

Next, the plurality of third frame portions 230 can be provided on the plurality of second frame portions 220, respectively. At least one second hole 232b and at least one second oblique hole 234b can be provided in the third frame portions 230. The second hole 232b and the second oblique hole 234b can be provided in the same third frame portion 230. Alternatively, the second hole 232b and the second oblique hole 234b can be provided in different third frame portions 230, respectively.

The second hole 232b can be connected to the first hole 232a of the second frame portion 220, and the second oblique hole 234b can be connected to the first oblique hole 234a of the second frame portion 220.

In addition, at least one groove 236a can be provided at a top surface of the third frame portion 230. The groove 236a can be provided in the third frame portion 230 which is the same as that provided with the second hole 232b and/or the second oblique hole 234b. Alternatively, the groove 236a can be provided in the third frame portion 230 which is different from that provided with the second hole 232b and/or the second oblique hole 234b.

A depth of the groove 236a can be smaller than a thickness of the third frame portion 230, and the groove 236a may not be provided in the second frame portion 220. The depth of the groove 236a can be several tens of μm or more, and the thickness of the third frame portion 230 can be several hundreds of μm or more.

The third frame portion 230 can be formed of the same material as the first and second frame portions 210 and 220. For example, the first and second frame portions 210 and 220 and the third frame portion 230 can be formed of a nickel-iron alloy containing about 64% iron (Fe) and about 36% nickel (Ni), and the nickel-iron alloy can contain a trace amount of at least one of carbon (C), sulfur (S), chromium (Cr), manganese (Mn), and silicon (Si). However, embodiments of the present disclosure are not limited thereto.

The third frame portion 230 can have the thickness of 300 μm or more. The hardness of the third frame portion 230 can be 150 Hv to 250 Hv. The density of the third frame portion 230 can be smaller than or equal to the density of the first and second frame portions 210 and 220. For example, the density of the third frame portion 230 can be 90% or more of the density of the first and second frame portions 210 and 220. In addition, the porosity of the third frame portion 230, that is, the proportion of voids formed inside, can be 10% or less, preferably, 2% or less.

Meanwhile, the adhesion between the third frame portion 230 and the second frame portion 220 can be 10 MPa or more, and the thermal expansion coefficient of the third frame portion 230 can be substantially the same as or similar to the thermal expansion coefficient of the first and second frame portions 210 and 220.

As such, the reproduced mask frame including the first, second, and third frame portions 210, 220, and 230 can have the height corresponding to the initial first height h1 and can be reused to form the light-emitting layer 170 of FIG. 1.

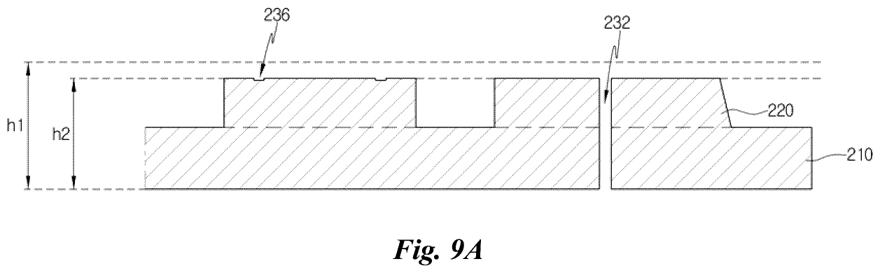

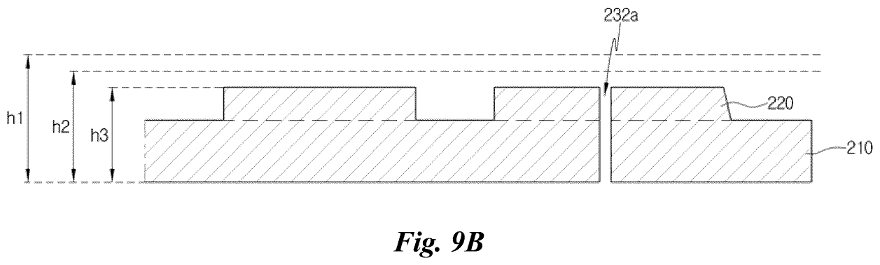

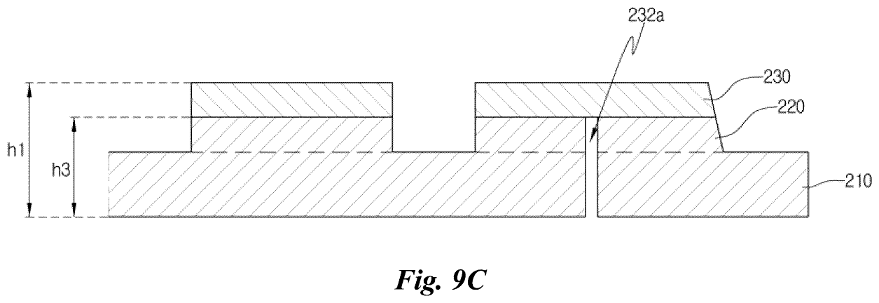

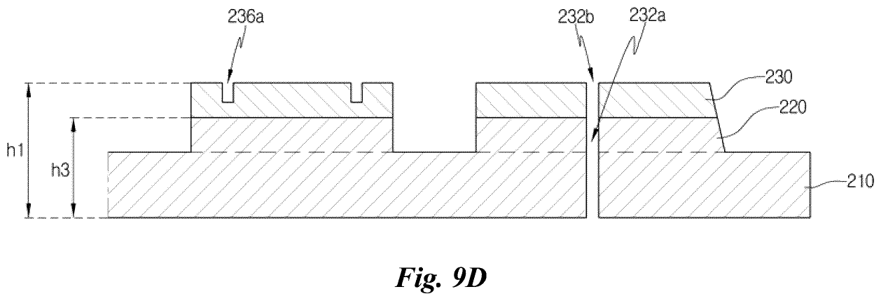

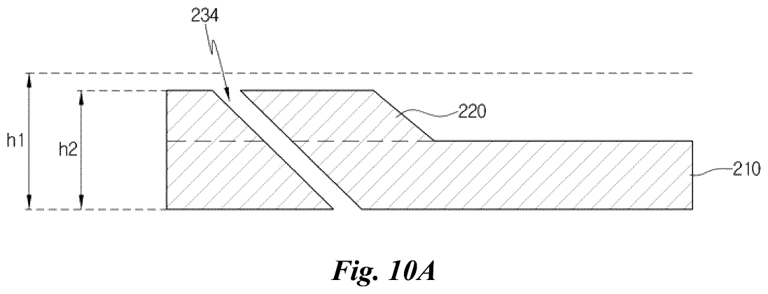

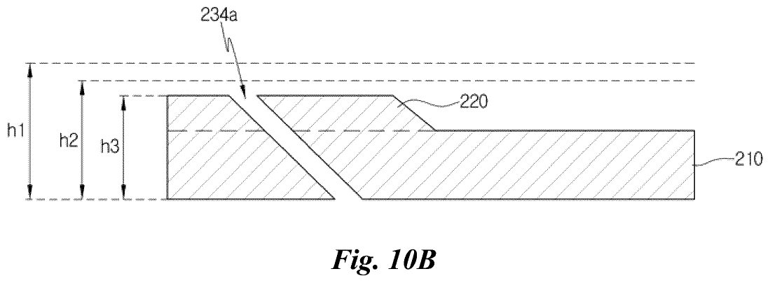

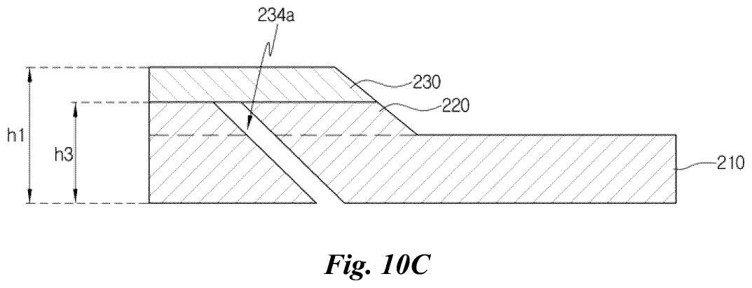

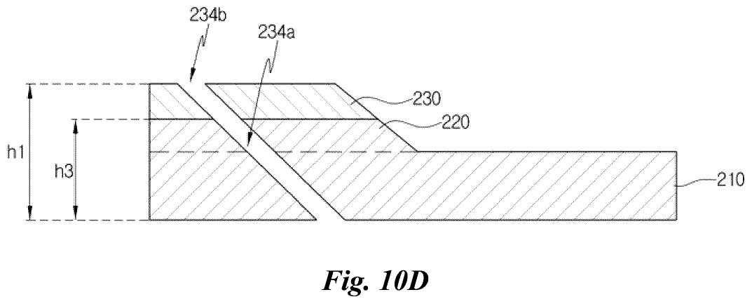

Hereinafter, a method of reproducing a mask frame according to the embodiment of the present disclosure will be described with reference to FIGS. 9A to 9D and FIGS. 10A to 10D.

FIGS. 9A to 9D and FIGS. 10A to 10D are schematic cross-sectional views of a mask frame in steps of reproducing the same according to the embodiment of the present disclosure, and will be described with reference to FIGS. 3 to 8 together. FIGS. 9A to 9D show a part of the mask frame, and FIGS. 10A to 10D show another part of the mask frame.

In FIG. 9A and FIG. 10A, the mask frame 200 can be repeatedly polished and welded, and the height of the mask frame 200 can be lowered, so that the mask frame 200 can have the second height h2. In this case, the depths of the hole 232, the oblique hole 234, and the groove 236 can also be reduced.

Next, in FIG. 9B and FIG. 10B, preprocessing can be performed on the second frame portion 220 of the mask frame 200 having the second height h2, thereby flattening the top surface of the second frame portion 220. In this case, the preprocessing can be performed through a polishing process, and the top surface of the second frame portion 220 can be partially removed. Accordingly, the preprocessed mask frame 200 can have a third height h3 lower than the second height h2.

Alternatively, in other embodiments, the preprocessing can be performed through a welding process, and the groove 236 provided at the top surface of the second frame portion 220 can be filled. In this case, the preprocessed mask frame 200 can have the second height h2.

Then, to increase adhesion of a material to be coated later, surface processing can be performed on the top surface of the preprocessed second frame portion 220, thereby forming surface roughness. In addition, if necessary, a cleaning or sanding process can be performed before or after the surface processing.

Next, in FIG. 9C and 10C, the third frame portion 230 can be formed on the preprocessed second frame portion 220. In this case, after forming a coating layer by coating metal powder, the coating layer can be processed and/or polished to thereby form the third frame portion 230.

For example, the metal power can be a nickel-iron alloy containing about 64% iron (Fe) and about 36% nickel (Ni). The metal powder can have a size of about 3 μm or more and can be coated through a cold spray method, a thermal spray method, or an atmospheric plasma spray method.

Meanwhile, in order to maintain the physical properties and shape of the mask frame, if necessary, heat treatment of the mask frame with the coating layer can be performed before processing and/or polishing the coating layer. For example, the heat treatment can be performed at a temperature of about 300 degrees of Celsius or higher for 2 hours or more, but embodiments of the present disclosure are not limited thereto.

Next, in FIG. 9D and FIG. 10D, post-processing can be performed on the third frame portion 230 to thereby form the second hole 232b, the second oblique hole 234b, and the groove 236a. The second hole 232b can be connected to the first hole 232a of the second frame portion 220, and the second oblique hole 234b can be connected to the first oblique hole 234a of the second frame portion 220. The groove 236a can be provided only at the top surface of the third frame portion 230 and can have a depth smaller than the thickness of the third frame portion 230.

As such, in the embodiment of the present disclosure, by reproducing the mask frame with the reduced height through the repetitive polishing and welding works, the height of the mask frame can be restored, and structures can be formed in the mask frame, so that the reproduced mask frame can be reused to form the light-emitting layer. Accordingly, the manufacturing costs can be reduced.

Meanwhile, in order to prevent cracks or dents from occurring during the processing and/or polishing process of the coating layer, processing and/or polishing conditions such as revolutions per minute (RPM), speed, and/or stroke power can be adjusted.

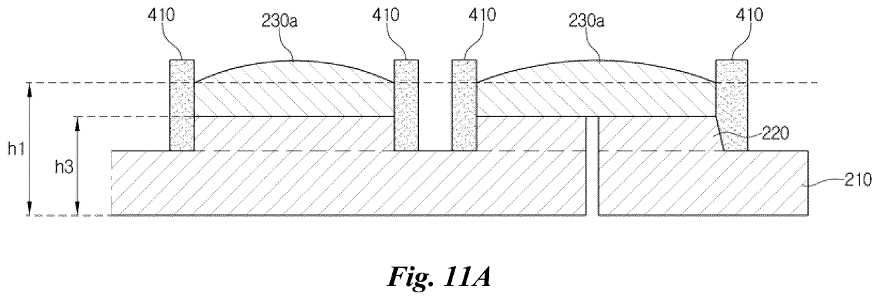

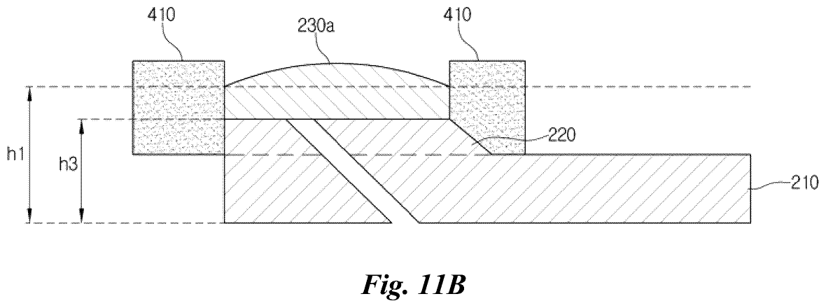

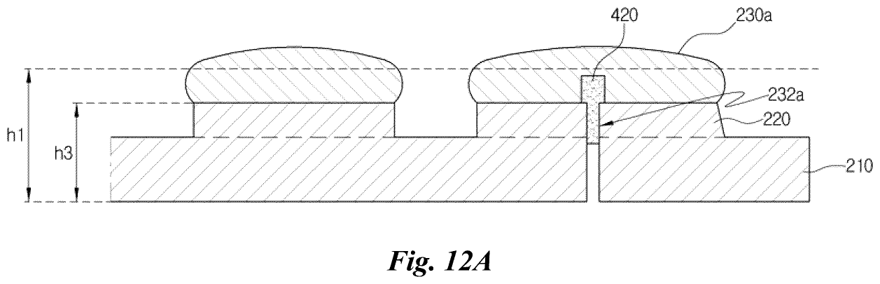

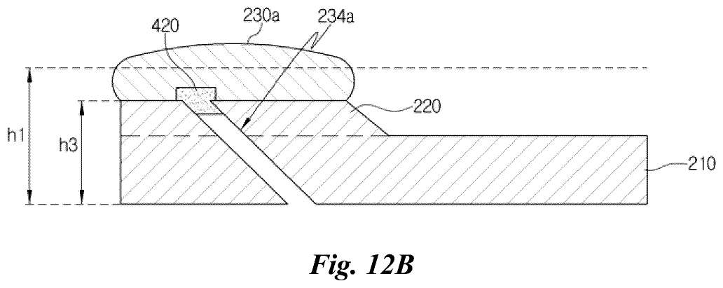

Alternatively, cracks or dents can be prevented by using an instrument, and this will be described with reference to FIGS. 11A and 11B and FIGS. 12A and 12B.

FIGS. 11A and 11B are schematic cross-sectional views of a mask frame in steps of reproducing the same using an instrument according to the embodiment of the present disclosure and will be described with reference to FIGS. 9A to 9D and FIGS. 10A to 10D.

In FIGS. 11A and 11B, a first jig 410 can be provided on at least one side of the preprocessed second frame portion 220 of FIG. 9B and FIG. 10B, and a coating layer 230a can be formed on the top surface of the second frame portion 220.

The first jig 410 can be a masking jig to protect a side surface of the second frame portion 220. The first jig 410 can be formed of silicon (Si) or metal, but embodiments of the present disclosure are not limited thereto.

Accordingly, the coating layer 230a may not be formed on the side surface of the second frame portion 220. In this case, the coating layer 230a can have a shape of curves or unevenness and roughness at its top surface.

Next, the coating layer 230a can be processed and/or polished, thereby forming the third frame portion 230 of FIG. 9C and FIG. 10C.

FIGS. 12A and 12B are schematic cross-sectional views of a mask frame in steps of reproducing the same using another instrument according to the embodiment of the present disclosure and will be described with reference to FIGS. 9A to 9D and FIGS. 10A to 10D.

In FIGS. 12A and 12B, a second jig 420 can be provided to correspond to the first hole 232a and the first oblique hole 234a of the preprocessed second frame portion 220 of FIG. 9B and FIG. 10B, and a coating layer 230a can be formed on the top surface of the second frame portion 220.

The second jig 420 can be a hole protection jig and have a substantially T-like shape. The second jig 420 can fill and cover the upper part of each of the first hole 232a and the first oblique hole. The second jig 420 can be formed of silicon (Si) or metal, but embodiments of the present disclosure are not limited thereto.

Accordingly, the coating layer 230a may not be formed in the first hole 232a and the first oblique hole 234a. In this case, the coating layer 230a can have a shape of curves or unevenness and roughness at its top surface.

Next, the coating layer 230a can be processed and/or polished, thereby forming the third frame portion 230 of FIG. 9C and FIG. 10C.

In the present disclosure, the mask frame with the reduced height through the repetitive polishing and welding works can be reproduced and reused. Accordingly, the manufacturing costs can be reduced.

In addition, by recycling the mask frame, production hazards/regulatory substances can be reduced.

It will be apparent to those skilled in the art that various modifications and variations can be made in the display device of the present disclosure without departing from the technical idea or scope of the disclosure. Thus, it is intended that the present disclosure cover the modifications and variations of this disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A mask frame, comprising:
a first frame portion;
a second frame portion on the first frame portion;
a third frame portion on the second frame portion;
a first hole provided in each of the first frame portion and the second frame portion; and
a second hole provided in the third frame portion and in fluid communication with the first hole.

2. The mask frame of claim 1, further comprising at least one groove in the third frame portion.

3. The mask frame of claim 2, wherein a depth of the at least one groove is less than a thickness of the third frame portion.

4. The mask frame of claim 1, wherein the second frame portion is one of a plurality of second frame portions provided on the first frame portion, and the third frame portion is provided on each of the plurality of second frame portions.

5. The mask frame of claim 1, wherein the second frame portion includes a filled groove at a top surface thereof.

6. The mask frame of claim 1, wherein the third frame portion has a thickness of 300 μm or more.

7. The mask frame of claim 1, wherein a density of the third frame portion is less than a density of each of the first and second frame portions.

8. The mask frame of claim 1, wherein the third frame portion is a metal powder layer on the second frame portion.

9. A method of producing a mask frame, the method comprising:
preparing a first frame portion and a second frame portion on the first frame portion;
forming a first hole in each of the first frame portion and the second frame portion;
flattening a top surface of the second frame portion;
forming a third frame portion on the second frame portion; and
forming a second hole in the third frame portion in fluid communication with the first hole.

10. The method of claim 9, wherein the method further includes forming at least one groove in the third frame portion.

11. The method of claim 9, wherein forming the third frame portion includes:
forming a metal powder coating layer on the second frame portion; and
processing or polishing, or both, the coating layer.

12. The method of claim 11, wherein forming the third frame portion further includes providing a jig on a side surface of the second frame portion or providing a jig in the first hole before forming the coating layer, or both.

13. A mask frame, comprising:
a plurality of frame elements including at least a first frame element and a second frame element stacked on each other;
a first hole in the first frame element; and
a second hole in the second frame element and aligned with the first hole.

14. The mask frame of claim 13, wherein the plurality of frame elements includes a third frame element between the first frame element and the second frame element.

15. The mask frame of claim 14, wherein the third frame element includes the first hole.

16. The mask frame of claim 15, wherein the third frame element includes at least one groove.

17. The mask frame of claim 13, wherein the second frame element includes at least one groove.

18. The mask frame of claim 13, wherein the second frame element is a metal powder coating layer on the first frame element.
